(19) United States
(12) Patent Application Publication
(10) Pub. No.: US 2015/0364407 A1
(43) Pub. Date: Dec. 17, 2015

(54) PACKAGE BOARD AND PACKAGE USING THE SAME

(71) Applicant: SAMSUNG ELECTRO-MECHANICS CO., LTD., Suwon-Si (KR)

(72) Inventors: Se Rang IM, Suwon-Si (KR); Seung Eun Lee, Suwon-Si (KR); Seung Yeop Kook, Suwon-Si (KR); Myung Sam Kang, Suwon-Si (KR)

(73) Assignee: SAMSUNG ELECTRO-MECHANICS CO., LTD., Suwon-Si (KR)

(21) Appl. No.: 14/607,074

(22) Filed: Jan. 28, 2015

(30) Foreign Application Priority Data
Jun. 12, 2014 (KR) 10-2014-0071612

(51) Int. Cl. H01L 23/498; H01L 49/02

(52) U.S. Cl. CPC H01L 23/49827; H01L 28/60; H01L 23/49838

(57) ABSTRACT

There are provided a package board and a package using the same. The package board according to an exemplary embodiment of the present disclosure includes: an insulating layer; a circuit pattern formed in the insulating layer; a capacitor formed on a whole surface of a horizontal plane in the insulating layer; and a first via penetrating through the capacitor and electrically connecting the circuit patterns each formed on upper and lower portions of the capacitor to each other.

### CROSS-REFERENCE TO RELATED APPLICATION

This application claims the foreign priority benefit of Korean Patent Application No. 10-2014-0071612, filed on Jun. 12, 2014, entitled “Package Board and Package Using the Same” which is hereby incorporated by reference in its entirety into this application.

### BACKGROUND

Embodiments of the present disclosure relate to a package board and a package using the same.

An electronic industry has recently adopted a mounting technology using a multi-layer printed circuit board capable of implementing high densification and high integration upon mounting components in order to implement miniaturization and thinness of an electronic device.

A package on package (POP) in which an application process and a memory device are implemented as a single package form has been used to miniaturize most high performance smart phones and improve performance thereof. As the application process and the memory device are gradually implemented as high performance, an aspect for improving electrical characteristics of a board configuring the POP has been studied.

### RELATED ART DOCUMENT

### Patent Document

(Patent Document 1) U.S. Pat. No. 5,986,209

### SUMMARY

An aspect of the present disclosure may provide a package board including a capacitor having large capacitance and a package using the same.

An aspect of the present disclosure may also provide a package board capable of decreasing a signal transmission distance and a package using the same.

According to an aspect of the present disclosure, a package board may include: an insulating layer; a circuit pattern formed in the insulating layer; a capacitor formed on a whole surface of a horizontal plane in the insulating layer; and a first via penetrating through the capacitor and electrically connecting the circuit patterns each formed on upper and lower portions of the capacitor to each other.

The first via may be formed to be spaced apart from side surfaces of the capacitor.

According to another aspect of the present disclosure, a package may include: a package board including an insulating layer, a circuit pattern formed in the insulating layer, a capacitor formed on a whole surface of a horizontal plane in the insulating layer, and a first via penetrating through the capacitor and electrically connecting the circuit patterns each formed on upper and lower portions of the capacitor to each other; and an electronic component disposed over the package board.

The first via may be formed to be spaced apart from side surfaces of the capacitor.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an illustrative view showing a package board according to a first exemplary embodiment of the present disclosure;

FIGS. 2 through 11 are illustrative views showing a method of manufacturing a package board according to a first exemplary embodiment of the present disclosure;

FIG. 12 is an illustrative view showing a package board according to a second exemplary embodiment of the present disclosure;

FIGS. 13 through 19 are illustrative views showing a method of manufacturing a package board according to a second exemplary embodiment of the present disclosure; and

FIG. 20 is an illustrative view showing a package formed using the package board according to the first exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### First Exemplary Embodiment

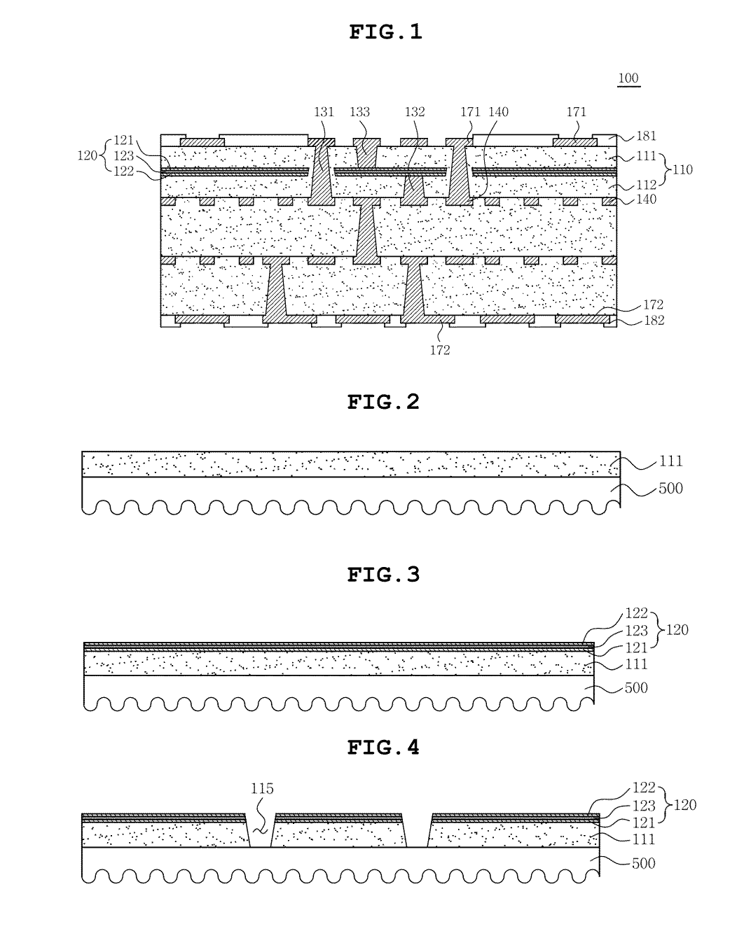

FIG. 1 is an illustrative view showing a package board according to a first exemplary embodiment of the present disclosure.

Referring to FIG. 1, the package board 100 according to a first exemplary embodiment of the present disclosure includes an insulating layer 110, a capacitor 120, a circuit pattern, and a first via 131. In addition, the package board 100 according to a first exemplary embodiment of the present disclosure may further have a second via, a first protecting layer 181 and a second protecting layer 182 formed therein.

According to an exemplary embodiment of the present disclosure, the insulating layer 110 may be made of a complex polymer resin typically used as an interlayer insulating material. For example, the insulating layer 110 may be made of a prepreg, Ajinomoto Build up Film (ABF), and an epoxy based resin such as FR-4, Bismaleimide Triazine (BT), or the like. However, in an exemplary embodiment of the present disclosure, a material of forming the insulating layers 110 is not limited thereto. The insulating layer 110 may be selected from insulating materials known in the field of circuit board.

According to an exemplary embodiment of the present disclosure, the capacitor 120 is formed to be buried in the insulating layer 110. In addition, the capacitor 120 according to an exemplary embodiment of the present disclosure is formed on a whole surface of a horizontal plane in the insulating layer 110. In this case, according to an exemplary embodiment of the present disclosure, in the case in which the second via penetrating through the capacitor 120 is formed, the capacitor 120 is formed in a region except for a region in which the second via is formed. In addition, the capacitor 120 is formed to be spaced apart from side surfaces of the second via in order to perform insulation from the second via.

The capacitor 120 according to an exemplary embodiment of the present disclosure includes a dielectric layer 123, a lower electrode 122, and an upper electrode 121. In addition, the capacitor 120 has a structure in which the dielectric layer 123 is interposed between the upper electrode 121 and the lower electrode 122.

According to an exemplary embodiment of the present disclosure, the dielectric layer 123 is formed on a first insulating layer 111. The dielectric layer 123 may be made of any material of dielectric materials used in a capacitor field.

In addition, the lower electrode 122 and the upper electrode 121 according to an exemplary embodiment of the present disclosure are made of a conductive material. For example, the lower electrode 122 and the upper electrode 121 may be made of copper (Cu). However, a material of the lower electrode 122 and the upper electrode 121 is not limited to copper and any material may be used as long as it is used as an electrode in the capacitor field.

According to an exemplary embodiment of the present disclosure, since the capacitor 120 is formed on the whole surface of the insulating layer 110, capacitance thereof is increased. A noise blocking function is improved by the capacitor having the large capacitance as described above, thereby improving reliability for signal transmission.

According to an exemplary embodiment of the present disclosure, the circuit pattern is formed in the insulating layer 110. The circuit pattern according to an exemplary embodiment of the present disclosure is classified into an inner layer circuit pattern 140 and an outer layer circuit pattern.

The inner layer circuit pattern 140 according to an exemplary embodiment of the present disclosure is formed in the insulating layer 110. Although FIG. 1 shows a case in which the inner layer circuit pattern 140 is formed below the capacitor 120, a position in which the inner layer circuit pattern 140 is formed is not limited thereto. That is, the inner layer circuit pattern 140 according to an exemplary embodiment of the present disclosure may be formed on the capacitor 120 and may be formed in any position in the insulating layer 110.

The outer layer circuit pattern according to an exemplary embodiment of the present disclosure is classified into a first outer layer circuit pattern 171 and a second outer layer circuit pattern 172.

According to an exemplary embodiment of the present disclosure, the first outer layer circuit pattern 171 is formed on an upper surface of the insulating layer 110 and is formed to be protruded from the insulating layer 110. In addition, according to an exemplary embodiment of the present disclosure, the second outer layer circuit pattern 172 is formed on a lower surface of the insulating layer 110 and is formed to be protruded from the insulating layer 110.

According to an exemplary embodiment of the present disclosure, the first outer layer circuit pattern 171 and the second outer layer circuit pattern 172 may be electrically connected to external configuring units such as an electronic component, a package, and a board, and the like.

In an exemplary embodiment of the present disclosure, the circuit pattern has been described by classifying it into the inner layer circuit pattern 140, the first outer layer circuit pattern 171 and the second outer layer circuit pattern 172. However, the classification of the circuit pattern is for convenience of explanation, and the circuit pattern is not necessarily classified as described above. That is, the position, the number of layers, and a function of the circuit pattern may be changed according to a selection of those skilled in the art.

The circuit pattern according to an exemplary embodiment of the present disclosure may be made of a conductive material used in a field of circuit board. For example, the circuit pattern may be made of copper.

According to an exemplary embodiment of the present disclosure, the first via 131 is formed in the insulating layer 110 to thereby penetrate through the capacitor 120, thereby electrically connecting the circuit patterns to each other. For example, the first via 131 penetrates through the capacitor 120 to thereby electrically connect the first outer layer circuit pattern 171 and the inner layer circuit pattern 140 to each other. In addition, in order to electrically insulate between the first via 131 and the capacitor 120, the capacitor 120 is formed to be spaced apart from side surfaces of the first via 131.

In this case, the insulating layer 110 is formed in a space spaced between the side surfaces of the first via 131 and the capacitor 120.

According to an exemplary embodiment of the present disclosure, a signal transmission distance between the first outer layer circuit pattern 171 and the inner layer circuit pattern 140 is decreased by the first via 131 formed to penetrate through the capacitor 120.

In addition, in the case in which the first outer layer circuit pattern 171 is electrically connected to an electronic component (not shown) disposed on the package board 100, a signal transmission distance between the electronic component (not shown) and the inner layer circuit pattern 140 is decreased.

According to an exemplary embodiment of the present disclosure, the second via is formed in the insulating layer 110 to thereby electrically connect the circuit pattern and the capacitor 120 to each other. According to an exemplary embodiment of the present disclosure, the second via is classified into a 2-1-th via 132 and a 2-2-th via 133.

According to an exemplary embodiment of the present disclosure, the 2-1-th via 132 electrically connects the inner layer circuit pattern 140 and the lower electrode 122 of the capacitor 120 to each other.

In addition, according to an exemplary embodiment of the present disclosure, the 2-2-th via 133 electrically connects the first outer layer circuit pattern 171 and the upper electrode 121 of the capacitor 120 to each other. In the case in which the first outer layer circuit pattern 171 is electrically connected to an electronic component (not shown) by the 2-2-th via 133 formed as described above, a signal transmission distance between the electronic component (not shown) and the capacitor 120 is decreased.

The first via 131 and the second via according to an exemplary embodiment of the present disclosure are made of a conductive material used in the field of circuit board. For example, the first via 131 and the second via may be made of copper.

According to an exemplary embodiment of the present disclosure, the first protecting layer 181 is formed on the insulating layer 110 and the first outer layer circuit pattern 171 and is formed to protect the first outer layer circuit pattern 171. In addition, the first protecting layer 181 according to an exemplary embodiment of the present disclosure is formed to expose a portion of the first outer layer circuit pattern 171. Here, the first outer layer circuit pattern 171 having the portion thereof exposed by the first protecting layer 181 may be a portion electrically connected to the external configuring unit.

According to an exemplary embodiment of the present disclosure, the second protecting layer 182 is formed below the insulating layer 110 and the second outer layer circuit pattern 172 and is formed to protect the second outer layer circuit pattern 172. In addition, the second protecting layer 182 according to an exemplary embodiment of the present disclosure is formed to expose a portion of the second outer layer circuit pattern 172. Here, the second outer layer circuit pattern 172 having the portion thereof exposed by the second protecting layer 182 may be a portion electrically connected to the external configuring unit.

FIGS. 2 through 11 are illustrative views showing a method of manufacturing a package board according to a first exemplary embodiment of the present disclosure.

Referring to FIG. 2, a first insulating layer 111 is formed on a carrier substrate 500.

The carrier substrate 500 according to an exemplary embodiment of the present disclosure is to support the circuit pattern, the insulating layer, and the like when forming the circuit pattern, the insulating layer, and the like.

According to an exemplary embodiment of the present disclosure, the carrier substrate 500 may be made of an insulating material or a metal material. Alternatively, the carrier substrate 500 may have a laminate plate structure in which a metal member is formed on one surface or both surfaces of the insulating material.

The first insulating layer 111 according to an exemplary embodiment of the present disclosure may be made of a complex polymer resin typically used as an interlayer insulating material. For example, the first insulating layer 111 may be made of a prepreg, Ajinomoto Build up Film (ABF), and an epoxy based resin such as FR-4, Bismaleimide Triazine (BT), or the like. However, in an exemplary embodiment of the present disclosure, a material of forming the first insulating layers 111 is not limited thereto. The first insulating layer 111 may be selected from insulating materials known in the field of circuit board.

Referring to FIG. 3, the capacitor 120 is formed on the first insulating layer 111.

According to an exemplary embodiment of the present disclosure, the capacitor 120 is formed on a whole surface of the first insulating layer 111.

The capacitor 120 according to an exemplary embodiment of the present disclosure, which is a film type capacitor, has a structure including the upper electrode 121, the lower electrode 122, and the dielectric layer 123 interposed between the upper electrode 121 and the lower electrode 122.

According to an exemplary embodiment of the present disclosure, the capacitor 120 may be formed by a method in which it is laminated on the first insulating layer 111 after being separately formed.

In addition, according to an exemplary embodiment of the present disclosure, the capacitor 120 may be formed by a method in which the upper electrode 121, the dielectric layer 123, and the lower electrode 122 are sequentially laminated on the first insulating layer 111. In this case, the upper electrode 121 and the lower electrode 122 may be formed by a plating method or may be formed by a method of laminating a metal foil. In addition, the dielectric layer 123 may be formed by applying a dielectric material in a liquid form or laminating the dielectric material in a film form on the upper electrode 121.

According to an exemplary embodiment of the present disclosure, the upper electrode 121 and the lower electrode 122 are made of a conductive material used in a field of circuit board. For example, the upper electrode 121 and the lower electrode 122 may be made of copper. In addition, according to an exemplary embodiment of the present disclosure, the dielectric material may be any material of dielectric materials used in the capacitor field.

Referring to FIG. 4, an opening part 115 is formed.

According to an exemplary embodiment of the present disclosure, the opening part 115 is formed to penetrate through the capacitor 120 and the first insulating layer 111 to thereby expose a portion of the carrier substrate 500. In this case, a region in which the opening part 115 is formed is a region in which the first via (not shown) is to be formed later. In addition, in order to insulate between the capacitor 120 and the first via (not shown), the opening part 115 is formed to have a diameter larger than that of the first via (not shown). The opening part 115 according to an exemplary embodiment of the present disclosure may be formed by using a laser drill or an exposure and development method.

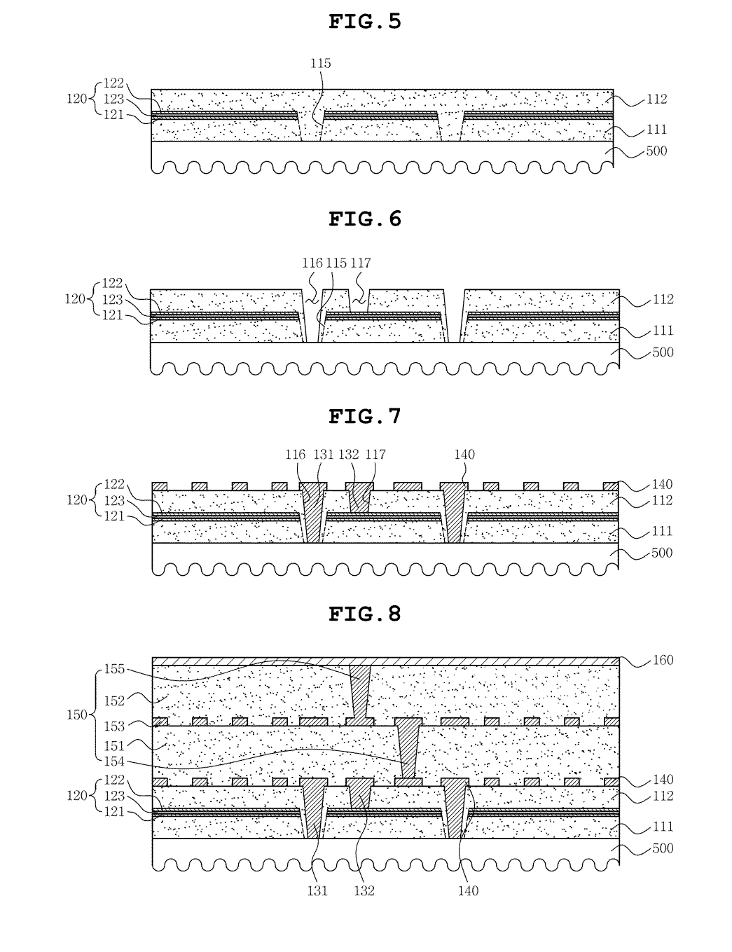

Referring to FIG. 5, a second insulating layer 112 is formed.

According to an exemplary embodiment of the present disclosure, the second insulating layer 112 is formed on the capacitor 120 and is formed to fill the opening part 115.

According to an exemplary embodiment of the present disclosure, the second insulating layer 112 is made of a complex polymer resin typically used as an interlayer insulating material. For example, the second insulating layer 112 may be made of a prepreg, Ajinomoto Build up Film (ABF), and an epoxy based resin such as FR-4, Bismaleimide Triazine (BT), or the like. However, a material forming the second insulating layer 112 according to an exemplary embodiment of the present disclosure is not limited thereto, and may be selected from insulating materials known in the field of circuit board.

Referring to FIG. 6, a first via hole 116 and a 2-1-th via hole 117 are formed.

According to an exemplary embodiment of the present disclosure, the first via hole 116 and the 2-1-th via hole 117 are formed in the second insulating layer 112.

According to an exemplary embodiment of the present disclosure, the first via hole 116 is formed to penetrate through the second insulating layer 112 filling the opening part 115 to thereby expose the portion of the carrier substrate 500. The first via hole 116 formed as described above is formed to be positioned in the opening part 115 and be spaced apart from the capacitor 120.

In addition, according to an exemplary embodiment of the present disclosure, the 2-1-th via hole 117 is formed to penetrate through the second insulating layer 112 formed on the capacitor 120 to thereby expose a portion of the capacitor 120. Here, the portion of the capacitor 120 exposed by the 2-1-th via 132 is a portion of the lower electrode 122.

According to an exemplary embodiment of the present disclosure, the first via hole 116 and the 2-1-th via hole 117 are formed by using the laser drill. However, a method of forming the first via hole 116 and the 2-1-th via hole 117 may be formed by using the laser drill as well as any method of methods of forming the via hole used in a field of circuit board such as an exposure and development method.

The first via hole 116 and the 2-1-th via hole 117 according to an exemplary embodiment of the present disclosure may be simultaneously formed or may be separately formed.

Referring to FIG. 7, the first via 131, the 2-1-th via 132, and the inner layer circuit pattern 140 are formed.

According to an exemplary embodiment of the present disclosure, the first via 131 is formed in the first via hole 116 and the 2-1-th via 132 is formed in the 2-1-th via hole 117.

In addition, according to an exemplary embodiment of the present disclosure, the inner layer circuit pattern 140 is formed on the first insulating layer 111. The inner layer circuit pattern 140 according to an exemplary embodiment of the present disclosure has a portion formed to be bonded to the first via 131 and the 2-1-th via 132.

The first via 131, the 2-1-th via 132, and the inner layer circuit pattern 140 according to an exemplary embodiment of the present disclosure may be formed by any method of methods of forming the via and the circuit pattern used in a field of circuit board. In addition, the first via 131, the 2-1-th via 132, and the inner layer circuit pattern 140 according to an exemplary embodiment of the present disclosure may be formed simultaneously or separately by using the method of forming the via and the circuit pattern. That is, the first via 131, the 2-1-th via 132, and the inner layer circuit pattern 140 may be simultaneously formed or after the first via 131 and the 2-1-th via 132 are formed, the inner layer circuit pattern 140 may be formed.

The first via 131, the 2-1-th via 132, and the inner layer circuit pattern 140 according to an exemplary embodiment of the present disclosure may be made of a conductive material used in a field of circuit board. For example, the first via 131, the 2-1-th via 132, and the inner layer circuit pattern 140 may be made of copper.

The first via 131 according to an exemplary embodiment of the present disclosure formed as described above is bonded to the inner layer circuit pattern 140 and penetrates through the capacitor 120. In addition, the first via 131 according to an exemplary embodiment of the present disclosure has side surfaces formed to be spaced apart from the capacitor 120. Here, the second insulating layer 112 is positioned in a space spaced between the side surfaces of the first via 131 and the capacitor 120, thereby performing insulation between the first via 131 and the capacitor 120.

In addition, the 2-1-th via 132 according to an exemplary embodiment of the present disclosure is boned to the lower electrode 122 of the capacitor 120 and the inner layer circuit pattern 140, respectively to thereby electrically be connected thereto.

Referring to FIG. 8, a build-up layer 150 and a metal layer 160 are formed.

According to an exemplary embodiment of the present disclosure, the build-up layer 150 is formed on the second insulating layer 112. The build-up layer 150 according to an exemplary embodiment of the present disclosure includes build-up insulating layers 151 and 152 and build-up circuit pattern 153 formed in the build-up insulating layers 151 and 152. In addition, the build-up layer 150 is provided with build-up vias 154 and 155 penetrating through the build-up insulating layers 151 and 152 to thereby electrically connect the build-up circuit pattern 153 and the inner layer circuit pattern 140 to each other. In addition, in the case in which the build-up circuit pattern 153 is formed in a multi-layer, the build-up vias 154 and 155 may be further formed to electrically connect between the build-up circuit patterns 153 formed in layers different from each other.

The build-up layer 150 according to an exemplary embodiment of the present disclosure may be formed by any method of forming the insulating layer, the circuit pattern, and the via known in the field of circuit board.

Although an exemplary embodiment of the present disclosure shows a structure in which the build-up layer 150 is formed to have the build-up insulating layers 151 and 152 of two layers, the build-up circuit pattern 153 of one layer, and the build-up vias 154 and 155 of two layers, the structure of the build-up layer 150 is not limited thereto. That is, according to an exemplary embodiment of the present disclosure, the build-up layer 150 may have the build-up insulating layers 151 and 152, the build-up circuit pattern 153, and the build-up vias 154 and 155 having the number of layers thereof or the number thereof changed according to a selection of those skilled in the art. For example, the build-up layer 150 may include only the build-up insulating layers 151 and 152 and the build-up vias 154 and 155 of one layer, having the build-up circuit pattern 153 omitted therein.

According to an exemplary embodiment of the present disclosure, the metal layer 160 is formed on the build-up layer 150. The metal layer 160 according to an exemplary embodiment of the present disclosure may be formed on the build-up insulating layers 151 and 152 and may be bonded to the build-up vias 154 and 155 in the case in which the build-up vias 154 and 155 are formed.

The metal layer 160 according to an exemplary embodiment of the present disclosure may be formed by laminating a metal foil on the build-up insulating layers 151 and 152. Alternatively, the metal layer 160 may be formed by performing the plating on the build-up insulating layers 151 and 152.

According to an exemplary embodiment of the present disclosure, the metal layer 160 may be formed simultaneously with the build-up vias 154 and 155 or may be separately formed after the build-up vias 154 and 155 are formed.

The metal layer 160 according to an exemplary embodiment of the present disclosure may be made of a conductive material used in a field of circuit board. For example, the metal layer 160 may be made of copper.

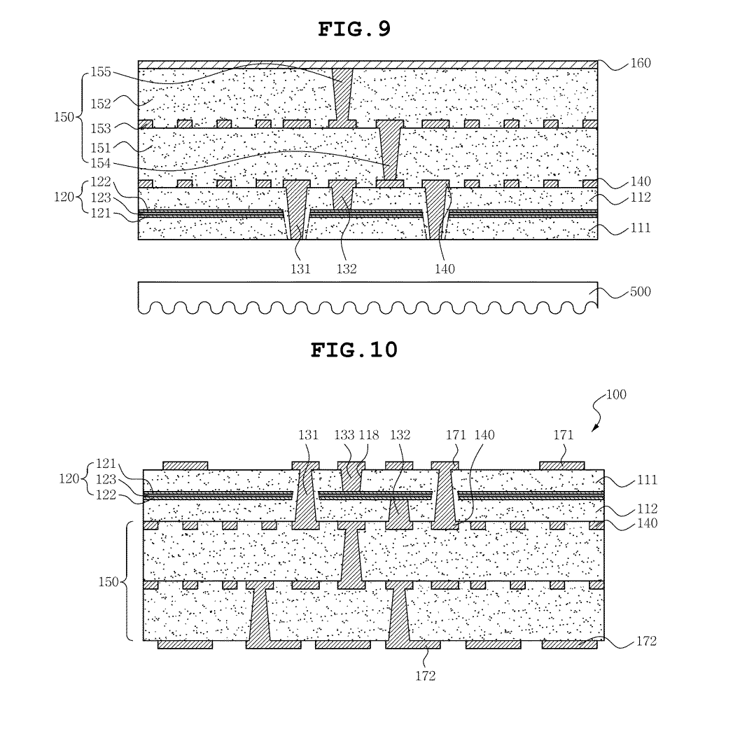

Referring to FIG. 9, the carrier substrate 500 is removed.

According to an exemplary embodiment of the present disclosure, the carrier substrate 500 is fully separated from the first insulating layer 111. However, in the case in which the carrier substrate 500 has a laminate structure of a multi-layer, a metal layer (not shown) on the outermost layer of the carrier substrate 500 may remain on the first insulating layer 111 and the residue may be removed. In this case, the metal layer (not shown) remaining on the first insulating layer 111 may be used later as the circuit pattern.

Referring to FIG. 10, a 2-2-th via 133, a first outer layer circuit pattern 171, and a second outer layer circuit pattern 172 are formed.

A package board 100 shown in FIG. 10 shows the package board 100 of FIG. 9 that top and bottom are reversed for convenience of explanation. Hereinafter, upper and lower directions will be described based on the described corresponding drawing.

According to an exemplary embodiment of the present disclosure, the 2-2-th via 133 is formed in the first insulating layer 111. According to an exemplary embodiment of the present disclosure, a 2-2-th via hole 118 is formed to penetrate through the first insulating layer 111 to thereby expose a portion of the upper electrode 121 of the capacitor 120. Next, the 2-2-th via 133 is formed by forming a conductive material in the 2-2-th via hole 118.

According to an exemplary embodiment of the present disclosure, the first outer layer circuit pattern 171 is formed on the first insulating layer 111 and is formed to be protruded from the first insulating layer 111. A portion of the first outer layer circuit pattern 171 formed as described above is electrically connected to the capacitor 120 by the 2-2-th via 133. In addition, the portion of the first outer layer circuit pattern 171 according to an exemplary embodiment of the present disclosure is electrically connected to the inner layer circuit pattern 140 by the first via 131.

The first outer layer circuit pattern 171 and the 2-2-th via 133 according to an exemplary embodiment of the present disclosure may be formed by any method of methods of forming the circuit pattern and the via known in the field of circuit board.

According to an exemplary embodiment of the present disclosure, the second outer layer circuit pattern 172 is formed by patterning the metal layer (of FIG. 9). Therefore, the second outer layer circuit pattern 172 according to an exemplary embodiment of the present disclosure is formed on a lower surface of the build-up layer 150 and is formed to be protruded from the build-up layer 150. A portion of the second outer layer circuit pattern 172 formed as described above may be electrically connected to the external configuring unit.

In an exemplary embodiment of the present disclosure, it has been described by way of example that the second outer layer circuit pattern 172 is formed by patterning the metal layer (of FIG. 9). However, a method of forming the second outer layer circuit pattern 172 is not limited thereto, and the second outer layer circuit pattern 172 may be formed by any method of methods of forming the circuit pattern known in the field of circuit board.

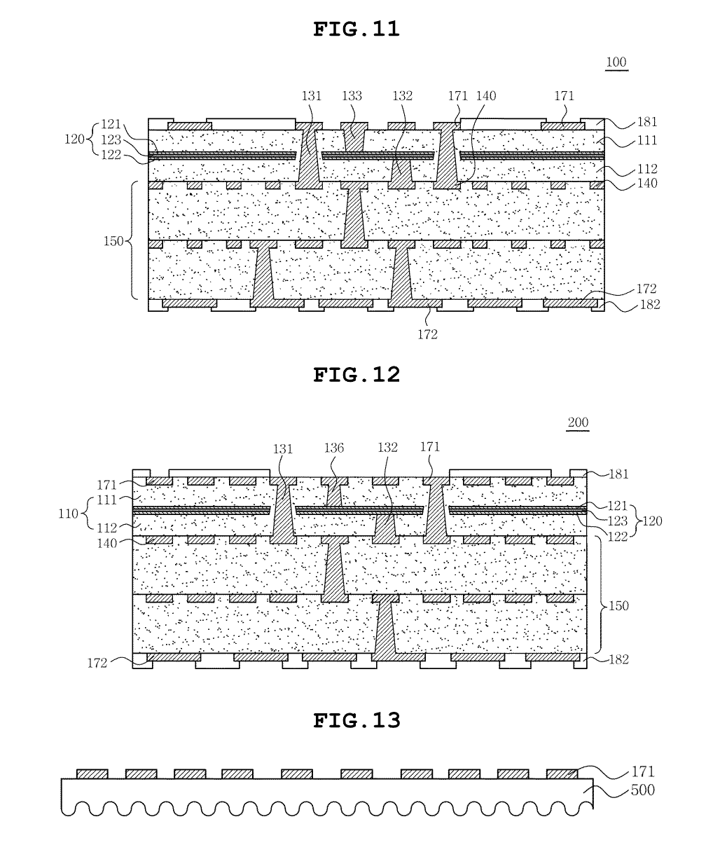

Referring to FIG. 11, the first protecting layer 181 and the second protecting layer 182 are formed.

According to an exemplary embodiment of the present disclosure, the first protecting layer 181, which is formed to protect the first outer layer circuit pattern 171, is formed on the first insulating layer 111 and the first outer layer circuit pattern 171. In this case, the first protecting layer 181 is formed so that a region connected to the external configuring unit among the first outer layer circuit pattern 171 is exposed to the outside. For example, the external configuring unit may be an electronic component, a board, a package, and the like, for example.

In addition, according to an exemplary embodiment of the present disclosure, the second protecting layer 182, which is formed to protect the second outer layer circuit pattern 172, is formed below the build-up layer 150 and the second outer layer circuit pattern 172. In this case, the second protecting layer 182 is formed so that a region connected to the external configuring unit among the second outer layer circuit pattern 172 is exposed to the outside.

According to an exemplary embodiment of the present disclosure, the first protecting layer 181 and the second protecting layer 182 may be made of a solder resist.

In addition, although not shown in the present drawing, a surface treating layer may be further formed on surfaces of the first outer layer circuit pattern 171 and the second outer layer circuit pattern 172 exposed by the first protecting layer 181 and the second protecting layer 182.

The package board 100 according to the first exemplary embodiment of the present disclosure of FIG. 1 may be formed by the method of FIGS. 2 through 11 as described above.

### Second Exemplary Embodiment

FIG. 12 is an illustrative view showing a package board according to a second exemplary embodiment of the present disclosure.

Since a package board 100 according to a second exemplary embodiment of the present disclosure has a difference in a structure of some configurations from the package board 100 according to the first exemplary embodiment of the present disclosure, a description of the same configuration will be simplified.

Referring to FIG. 12, the package board 100 according to the second exemplary embodiment of the present disclosure includes an insulating layer 110, a capacitor 120, a circuit pattern, and a first via 131. In addition, the package board 100 according to the second exemplary embodiment of the present disclosure may further have a second via, a first protecting layer 181 and a second protecting layer 182 formed therein.

According to an exemplary embodiment of the present disclosure, the insulating layer 110 may be made of a complex polymer resin typically used as an interlayer insulating material. According to an exemplary embodiment of the present disclosure, a material of the insulating layer 110 may be selected from insulating materials known in the field of circuit board.

According to an exemplary embodiment of the present disclosure, the capacitor 120 is formed to be buried in the insulating layer 110. In addition, the capacitor 120 according to an exemplary embodiment of the present disclosure is formed on a whole surface of a horizontal plane in the insulating layer 110. In this case, according to an exemplary embodiment of the present disclosure, in the case in which the first via 131 penetrating through the capacitor 120 is formed, the capacitor 120 is formed in a region except for a region in which the first via 131 is formed. In addition, in order to insulate between the first via 131 and the capacitor 120, the capacitor 120 is formed to be spaced apart from side surfaces of the first via 131.

The capacitor 120 according to an exemplary embodiment of the present disclosure includes a dielectric layer 123, a lower electrode 122, and an upper electrode 121. In addition, the capacitor 120 has a structure in which the dielectric layer 123 is interposed between the upper electrode 121 and the lower electrode 122.

According to an exemplary embodiment of the present disclosure, since the capacitor 120 is formed on the whole surface of the insulating layer 110, capacitance thereof is increased. A noise blocking function is improved by the capacitor 120 having the large capacitance as described above, thereby improving reliability for signal transmission.

The circuit pattern according to an exemplary embodiment of the present disclosure is classified into an inner layer circuit pattern 140 and an outer layer circuit pattern.

The inner layer circuit pattern 140 according to an exemplary embodiment of the present disclosure is formed in the insulating layer 110. Although FIG. 12 shows a case in which the inner layer circuit pattern 140 is formed below the capacitor 120, the inner layer circuit pattern 140 may be formed at any position in the insulating layer 110.

The outer layer circuit pattern according to an exemplary embodiment of the present disclosure is classified into a first outer layer circuit pattern 171 and a second outer layer circuit pattern 172.

According to an exemplary embodiment of the present disclosure, the first outer layer circuit pattern 171 is formed to be buried in an upper surface of the insulating layer 110. That is, the first outer layer circuit pattern 171 according to an exemplary embodiment of the present disclosure has an upper surface exposed from the insulating layer 110 and side surfaces and a lower surface formed to be buried in the insulating layer 110.

According to an exemplary embodiment of the present disclosure, the second outer layer circuit pattern 172 is formed on a lower surface of the insulating layer 110 and is formed to be protruded from the insulating layer 110.

According to an exemplary embodiment of the present disclosure, the first outer layer circuit pattern 171 and the second outer layer circuit pattern 172 may be electrically connected to external configuring units such as an electronic component, a package, and a board, and the like.

In an exemplary embodiment of the present disclosure, although the circuit pattern has been described by classifying it into the inner layer circuit pattern 140, the first outer layer circuit pattern 171 and the second outer layer circuit pattern 172, a position, the number of layers, a function, or the like of the circuit pattern may be changed according to a selection of those skilled in the art.

The circuit pattern according to an exemplary embodiment of the present disclosure may be made of a conductive material used in a field of circuit board. For example, the circuit pattern may be made of copper.

According to an exemplary embodiment of the present disclosure, the first via 131 is formed in the insulating layer 110 to thereby penetrate through the capacitor 120, thereby electrically connecting the circuit patterns to each other. For example, the first via 131 penetrates through the capacitor 120 to thereby electrically connect the first outer layer circuit pattern 171 and the inner layer circuit pattern 140 to each other. In addition, in order to electrically insulate between the first via 131 and the capacitor 120, the capacitor 120 is formed to be spaced apart from side surfaces of the first via 131. In this case, the insulating layer 110 is formed in a space spaced between the side surfaces of the first via 131 and the capacitor 120.

According to an exemplary embodiment of the present disclosure, a signal transmission distance between the first outer layer circuit pattern 171 and the inner layer circuit pattern 140 is decreased by the first via formed to penetrate through the capacitor 120. In addition, in the case in which the first outer layer circuit pattern 171 is electrically connected to an electronic component (not shown) disposed on the package board 100, a signal transmission distance between the electronic component (not shown) and the inner layer circuit pattern 140 is decreased.

According to an exemplary embodiment of the present disclosure, the second via is formed in the insulating layer 110 and is classified into a 2-1-th via 132 and a 2-3-th via 134.

In addition, according to an exemplary embodiment of the present disclosure, the 2-3-th via 134 electrically connects the first outer layer circuit pattern 171 and the upper electrode 121 of the capacitor 120 to each other. In the case in which the first outer layer circuit pattern 171 is electrically connected to an electronic component (not shown) by the 2-3-th via 134 formed as described above, a signal transmission distance between the electronic component (not shown) and the capacitor 120 is decreased.

The first via 131 and the second via according to an exemplary embodiment of the present disclosure are made of a conductive material used in the field of circuit board. For example, the first via 131 and the second via may be made of copper.

According to an exemplary embodiment of the present disclosure, the first protecting layer 181 is formed on the insulating layer 110 and the first outer layer circuit pattern 171 and is formed to protect the first outer layer circuit pattern 171. In addition, according to an exemplary embodiment of the present disclosure, the second protecting layer 182 is formed below the insulating layer 110 and the second outer layer circuit pattern 172 and is formed to protect the second outer layer circuit pattern 172.

FIGS. 13 through 19 are illustrative views showing a method of manufacturing a package board according to a second exemplary embodiment of the present disclosure.

Referring to FIG. 13, the first outer layer circuit pattern 171 is formed on the carrier substrate 500.

The carrier substrate 500 according to an exemplary embodiment of the present disclosure is to support the circuit pattern, the insulating layer, and the like when forming the circuit pattern, the insulating layer, and the like.

According to an exemplary embodiment of the present disclosure, the carrier substrate 500 may be made of an insulating material or a metal material. Alternatively, the carrier substrate 500 may have a laminate plate structure in which a metal member is formed on one surface or both surfaces of the insulating material.

According to an exemplary embodiment of the present disclosure, the first outer layer circuit pattern 171 may be formed by any method of methods of forming the circuit pattern known in the field of circuit board. In addition, the first outer layer circuit pattern according to an exemplary embodiment of the present disclosure may be made of a conductive material used in the field of circuit board. For example, the first outer layer circuit pattern 171 may be made of copper.

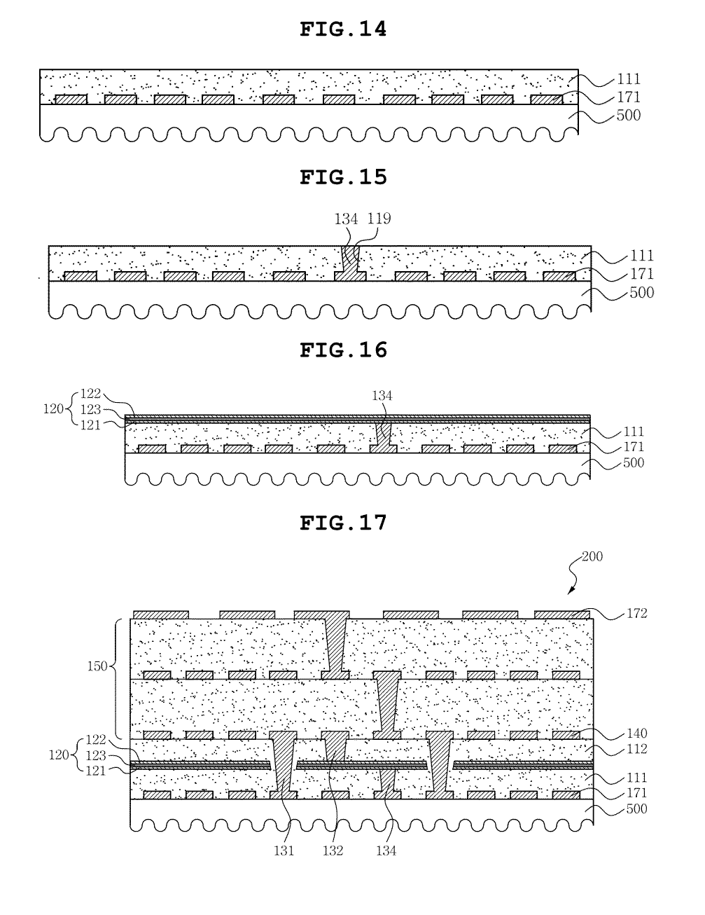

Referring to FIG. 14, a first insulating layer 111 is formed.

According to an exemplary embodiment of the present disclosure, the first insulating layer 111 is formed on the carrier substrate 500 and the first outer layer circuit pattern 171.

The first insulating layer 111 according to an exemplary embodiment of the present disclosure may be made of a complex polymer resin typically used as an interlayer insulating material. For example, the first insulating layer 111 may be made of a prepreg, Ajinomoto Build up Film (ABF), and an epoxy based resin such as FR-4, Bismaleimide Triazine (BT), or the like. However, in an exemplary embodiment of the present disclosure, a material of forming the first insulating layers 111 is not limited thereto. The first insulating layer 111 may be selected from insulating materials known in the field of circuit board.

Referring to FIG. 15, the 2-3-th via 134 is formed.

According to an exemplary embodiment of the present disclosure, a 2-3-th via hole 119 is formed in the first insulating layer 111 by the known method such as a laser drill, an exposure and development method, or the like. The 2-3-th via hole 119 according to an exemplary embodiment of the present disclosure is formed to penetrate through the first insulating layer 111 to thereby expose a portion of the first outer layer circuit pattern 171.

According to an exemplary embodiment of the present disclosure, the 2-3-th via 134 is formed by filling the 2-3-th via hole 119 with a conductive material. For example, the 2-3-th via 134 may be formed by performing the plating in the 2-3-th via hole 119. Alternatively, the 2-3-th via 134 may be formed by filling the 2-3-th via hole 119 with a conductive paste using a printing method. In addition to this, the 2-3-th via 134 may be formed by a method of forming the via known in the field of circuit board.

Referring to FIG. 16, the capacitor 120 is formed.

According to an exemplary embodiment of the present disclosure, the capacitor 120 is formed on the first insulating layer 111 and the 2-3-th via 134. Particularly, the capacitor 120 according to an exemplary embodiment of the present disclosure is formed on a whole surface of an upper surface of the first insulating layer 111.

A detailed description of the capacitor 120 according to an exemplary embodiment of the present disclosure makes reference to FIG. 3.

Referring to FIG. 17, the first via 131, the inner layer circuit pattern 140, the second insulating layer 112, the 2-1-th via 132, the build-up layer 150, and the second outer layer circuit pattern 172 are formed.

A detailed description of a method of forming the first via 131, the inner layer circuit pattern 140, the second insulating layer 112, the build-up layer 150, and the 2-1-th via 132 according to an exemplary embodiment of the present disclosure makes reference to FIGS. 4 through 8. In addition, a method of forming the second outer layer circuit pattern 172 according to an exemplary embodiment of the present disclosure makes reference to FIG. 10.

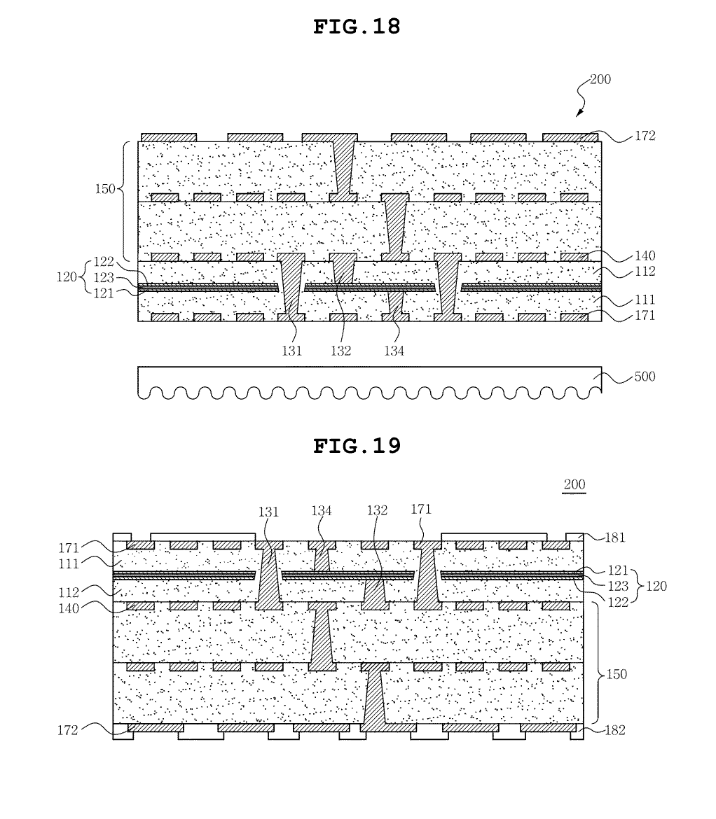

Referring to FIG. 18, the carrier substrate 500 is removed.

According to an exemplary embodiment of the present disclosure, the package board 100 from which the carrier substrate 500 is removed has a structure in which the first outer layer circuit pattern 171 is buried in the first insulating layer 111. In addition, according to an exemplary embodiment of the present disclosure, the second outer layer circuit pattern 172 has a structure protruded from the build-up layer 150 to the outside.

Referring to FIG. 19, the first protecting layer 181 and the second protecting layer 182 are formed.

A package board 100 shown in FIG. 19 shows the package board 100 of FIG. 18 that top and bottom are reversed for convenience of explanation. Hereinafter, upper and lower directions will be described based on the described corresponding drawing.

A detailed description of the first protecting layer 181 and the second protecting layer 182 according to an exemplary embodiment of the present disclosure makes reference to FIG. 11.

In addition, although not shown in the present drawing, a surface treating layer may be further formed on surfaces of the first outer layer circuit pattern 171 and the second outer layer circuit pattern 172 exposed by the first protecting layer 181 and the second protecting layer 182.

The package board 100 according to the second exemplary embodiment of the present disclosure of FIG. 12 may be formed by the method of FIGS. 13 through 19 as described above.

Although the first and second exemplary embodiments of the present disclosure show a case in which an operation of forming the build-up layer 150 is performed after the inner layer circuit pattern 140 is formed, the operation of forming the build-up layer 150 may be omitted according to a selection of those skilled in the art. For example, the inner layer circuit pattern 140 may be omitted and the second outer layer circuit pattern 172 may be formed in the second insulating layer 112.

In addition, in the method of manufacturing the package board, the insulating layer 110 of FIGS. 1 and 12 has been described by it classifying into the first insulating layer 111, the second insulating layer 112, and the build-up insulating layers 151 and 152 for convenience of explanation. In addition, in the method of manufacturing the package board, the inner layer circuit pattern 140 of FIGS. 1 and 12 has been classified into the inner layer circuit pattern 140 and the build-up circuit pattern 153. This is for convenience of explanation of the method of manufacturing the package board, and is not necessary to particularly be classified.

In addition, although an exemplary embodiment of the present disclosure shows and describes in the drawings a case in which the package board 100 is formed on one surface of the carrier substrate 500, the present disclosure is not limited thereto. That is, the package board 100 according to an exemplary embodiment of the present disclosure may be simultaneously formed on both surfaces of the carrier substrate 500. In this case, when the carrier substrate 500 is removed, two package boards 100 may be simultaneously obtained.

In order to improve a noise blocking function of the package board 100, a capacitor having large capacitance is required. To this end, according to the first and second exemplary embodiments of the present disclosure, the capacitor 120 is formed on the whole surface of the horizontal plane in the package board 100. However, in the case in which the capacitor 120 is formed on the whole surface of the horizontal plane in the package board 100, a signal path between upper and lower portions of the capacitor 120 becomes complex and a signal transmission distance is increased. Therefore, according to the first and second exemplary embodiments of the present disclosure, the signal path is simplified and the signal transmission distance is decreased by the first via 131 penetrating through the capacitor 120.

That is, the package board 100 according to the first and second exemplary embodiments of the present disclosure may implement an improvement of the noise blocking function and the decrease in the signal transmission distance by the capacitor 120 formed on the whole surface of the horizontal plane in the package board 100 and the first via 131 penetrating through the capacitor 120.

Package

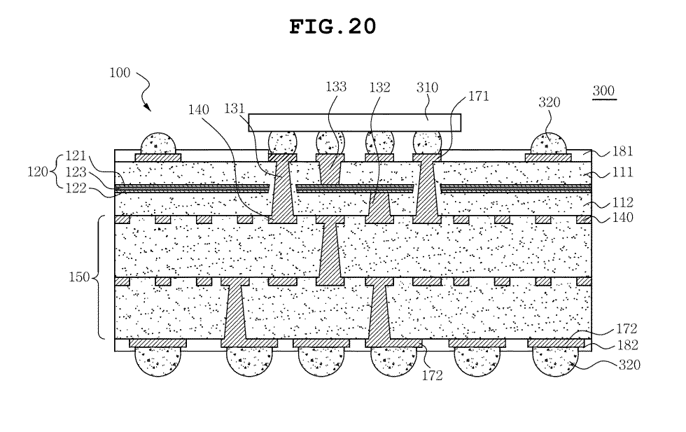

FIG. 20 is an illustrative view showing a package formed using the package board according to the first exemplary embodiment of the present disclosure.

A package 300 according to an exemplary embodiment of the present disclosure may have a package board 100 having an electronic component 310 mounted thereon, and a first external connecting terminal 320 and a second external connecting terminal 330 formed thereon.

Since the package board 100 according to an exemplary embodiment of the present disclosure is the package board 100 of FIG. 1, a detailed description of the package board 100 makes reference to FIG. 1.

According to an exemplary embodiment of the present disclosure, the electronic component 310 is disposed over the package board 100. For example, the electronic component 310 may be a memory device or an application process. However, the electronic component 310 is not limited to the memory device or the application process, and any kind of electronic component may be used as long as it is used in the package.

According to an exemplary embodiment of the present disclosure, a first outer layer circuit pattern 171 exposed to the outside by a first protecting layer 181 is disposed below the electronic component 310.

According to an exemplary embodiment of the present disclosure, the first outer layer circuit pattern 171 exposed by the first protecting layer 181 and the electronic component 310 may be electrically connected to each other by the first external connecting terminal 320.

According to an exemplary embodiment of the present disclosure, the first outer layer circuit pattern 171 is directly bonded to an inner layer circuit pattern 140 and a capacitor 120, respectively, through a first via 131 and a 2-2-th via 133. Therefore, since the electronic component 310 is also electrically connected to the first outer layer circuit pattern 171, an electrical signal transmission distance between the inner layer circuit pattern 140 and the capacitor 120 is decreased. As described above, as the electrical signal transmission distance is decreased, a signal transmission speed between the electronic component 310 and the inner layer circuit pattern 140 or between the electronic component 310 and the capacitor 120 is improved.

According to an exemplary embodiment of the present disclosure, the second external connecting terminal 330 is formed on the first outer layer circuit pattern 171 and the second outer layer circuit pattern 172 exposed by the first protecting layer 181 and the second protecting layer 182. The second external connecting terminal 330 according to an exemplary embodiment of the present disclosure serves to electrically connect external configuring units such as the package, a main board, a part, and the like to the package 300 according to an exemplary embodiment of the present disclosure.

The first external connecting terminal 320 and the second external connecting terminal 330 according to an exemplary embodiment of the present disclosure may be a solder ball or a solder bump.

In an exemplary embodiment of the present disclosure, a case in which the package board 100 according to the first exemplary embodiment of the present disclosure is used in the package 300 has been described by way of example. However, the package 300 according to an exemplary embodiment of the present disclosure may be formed by using the package board according to the second exemplary embodiment of the present disclosure as described above.

In addition, the package 300 according to an exemplary embodiment of the present disclosure may be used as a single package, but is not limited thereto. That is, although not shown as an exemplary embodiment of the present disclosure, the package 300 according to an exemplary embodiment of the present disclosure may be used for a package on package (POP) having different packages (not shown) and lamination structures.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A package board comprising:
an insulating layer;
a circuit pattern formed in the insulating layer;
a capacitor formed on a whole surface of a horizontal plane in the insulating layer; and
a first via penetrating through the capacitor and electrically connecting the circuit patterns each formed on upper and lower portions of the capacitor to each other.

2. The package board of claim 1, wherein the capacitor includes an upper electrode and a lower electrode formed on the whole surface of the horizontal plane in the insulating layer, and a dielectric layer interposed between the upper electrode and the lower electrode.

3. The package board of claim 1, wherein the circuit pattern is each formed on the upper portion and the lower portion of the capacitor.

4. The package board of claim 3, wherein the first via is formed to be spaced apart from side surfaces of the capacitor.

5. The package board of claim 1, further comprising a second via formed in the insulating layer to thereby electrically connect the circuit pattern and the capacitor to each other.

6. The package board of claim 1, wherein the circuit pattern includes an inner layer circuit pattern formed in the insulating layer.

7. The package board of claim 1, wherein the circuit pattern includes an outer layer circuit pattern formed on an upper surface of the insulating layer and formed to be protruded from the upper surface of the insulating layer.

8. The package board of claim 1, wherein the circuit pattern includes an outer layer circuit pattern buried in the insulating layer and having an upper surface formed to be exposed to the outside.

9. A package comprising:
a package board including an insulating layer, a circuit pattern formed in the insulating layer, a capacitor formed on a whole surface of a horizontal plane in the insulating layer, and a first via penetrating through the capacitor and electrically connecting the circuit patterns each formed on upper and lower portions of the capacitor to each other; and
an electronic component disposed over the package board.

10. The package of claim 9, wherein the circuit pattern is each formed on the upper portion and the lower portion of the capacitor.

11. The package of claim 10, wherein the first via is formed to be spaced apart from side surfaces of the capacitor.

12. The package of claim 9, further comprising a second via formed in the insulating layer to thereby electrically connect the circuit pattern and the capacitor to each other.

13. The package of claim 9, wherein the circuit pattern includes an inner layer circuit pattern formed in the insulating layer.

14. The package of claim 9, wherein the circuit pattern includes an outer layer circuit pattern formed on an upper surface of the insulating layer to be electrically connected to the electronic component.

15. The package of claim 14, wherein the outer layer circuit pattern is formed to be protruded from the upper surface of the insulating layer.

16. The package of claim 14, wherein the outer layer circuit pattern is formed to be buried in the insulating layer and have an upper surface exposed to the outside.

17. The package of claim 9, wherein the capacitor includes an upper electrode and a lower electrode formed on the whole surface of the horizontal plane in the insulating layer, and a dielectric layer interposed between the upper electrode and the lower electrode.
